(19) United States
(12) Patent Application Publication
(10) Pub. No.: US 2025/0359036 A1
(43) Pub. Date: Nov. 20, 2025

(54) MEMORY CELL AND MEMORY CELL ARRAY OF NON-VOLATILE MEMORY

(71) Applicant: eMemory Technology Inc., Hsin-Chu (TW)

(72) Inventors: Lun-Chun CHEN, Hsinchu County (TW); Hsin-Ming Chen, Hsinchu County (TW); Ping-Lung Ho, Hsinchu County (TW)

(21) Appl. No.: 19/194,317

(22) Filed: Apr. 30, 2025

Related U.S. Application Data
(60) Provisional application No. 63/647,111, filed on May 14, 2024.

(51) Int. Cl. H10B 20/25

(52) U.S. Cl. CPC H10B 20/25

(57) ABSTRACT

An antifuse-type one time programmable memory cell includes a first select transistor, a second select transistor and a first antifuse transistor. A first terminal of the first select transistor is connected with a first bit line. A gate terminal of the first select transistor is connected with a first word line. A first terminal of the second select transistor is connected with a second terminal of the first select transistor. A gate terminal of the second select transistor is connected with a second word line. A first terminal of the first antifuse transistor is connected with a second terminal of the second select transistor. A gate terminal of the first antifuse transistor is connected with a first antifuse line. When a program action is performed, both of the first select transistor and the second select transistor are turned on.

This application claims the benefit of U.S. provisional application Ser. No. 63/647,111, filed May 14, 2024, the subject matters of which is incorporated herein by reference.

### FIELD OF THE INVENTION

The present invention relates to a memory cell and a memory cell array, and more particularly to a memory cell and a memory cell array of a non-volatile memory.

### BACKGROUND OF THE INVENTION

As is well known, a non-volatile memory is able to continuously retain data after the supplied power is interrupted. Generally, after the non-volatile memory leaves the factory, the user may program the non-volatile memory in order to record data into the non-volatile memory.

According to the number of times the non-volatile memory is programmed, the non-volatile memories may be classified into a multi-time programmable memory (also referred as a MTP memory), a one-time programmable memory (also referred as an OTP memory) and a mask read only memory (also referred as a Mask ROM).

Generally, the MTP memory can be programmed many times, and the stored data of the MTP memory can be modified many times. On the contrary, the OTP memory can be programmed once. After the OTP memory is programmed, the stored data fails to be modified. Moreover, after the Mask ROM leaves the factory, all stored data have been recorded therein. The user is only able to read the stored data from the Mask ROM, but the user is unable to program the Mask ROM.

Moreover, depending on the characteristics, the OTP memories may be classified into two types, i.e., a fuse-type OTP memory and an antifuse-type OTP memory.

Before a memory cell of the fuse-type OTP memory is programmed, the memory cell has a low-resistance storage state. After the memory cell of the fuse-type OTP memory is programmed, the memory cell has a high-resistance storage state.

On the other hand, the memory cell of the antifuse-type OTP memory has the high-resistance storage state before programmed, and the memory cell of the antifuse-type OTP memory has the low-resistance storage state after programmed.

### SUMMARY OF THE INVENTION

An embodiment of the present invention provides a memory cell array of a non-volatile memory. The memory cell array includes a first antifuse-type one time programmable memory cell. The first antifuse-type one time programmable memory cell includes a first select transistor, a second select transistor and a first antifuse transistor. A first terminal of the first select transistor is connected with a first bit line. A gate terminal of the first select transistor is connected with a first word line. A first terminal of the second select transistor is connected with a second terminal of the first select transistor. Agate terminal of the second select transistor is connected with a second word line. A first terminal of the first antifuse transistor is connected with a second terminal of the second select transistor. A gate terminal of the first antifuse transistor is connected with a first antifuse line. When a program action is performed on the first antifuse-type one time programmable memory cell, a ground voltage is provided to the first bit line, a program voltage is provided to the first antifuse line, and both of the first select transistor and the second select transistor are turned on simultaneously. Consequently, a gate dielectric layer of the first antifuse transistor is ruptured and the first antifuse-type one time programmable memory cell is programmed into a ruptured state.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic top view illustrating an antifuse-type OTP memory cell according to a first embodiment of the present invention;

FIG. 1B is a schematic cross-sectional view illustrating the antifuse-type OTP memory cell according to the first embodiment of the present invention and taken along the direction AB;

FIGS. 2A and 2B schematically illustrate the bias voltages for programming the OTP memory cell of the first embodiment to a first storage state;

FIGS. 2C, 2D and 2E schematically illustrate the bias voltages for programming the OTP memory cell of the first embodiment to a second storage state;

FIGS. 2F and 2G schematically illustrate the bias voltages for performing a read action on the OTP memory cell of the first embodiment;

FIG. 3A schematically illustrates a first exemplary structure of a memory cell array composed of a plurality of OTP memory cells in the first embodiment of the present invention;

FIG. 3B schematically illustrates the bias voltages for programming the memory cell array shown in FIG. 3A;

FIG. 3C schematically illustrates the bias voltages for performing a read action on the memory cell array shown in FIG. 3A;

FIG. 4 schematically illustrates a second exemplary structure of a memory cell array composed of a plurality of OTP memory cells in the first embodiment of the present invention;

FIG. 5A is a schematic top view illustrating an antifuse-type OTP memory cell according to a second embodiment of the present invention;

FIG. 5B is a schematic cross-sectional view illustrating the antifuse-type OTP memory cell according to the second embodiment of the present invention and taken along the direction CD;

FIGS. 6A and 6B schematically illustrate the bias voltages for programming the OTP memory cell of the second embodiment to a first storage state;

FIGS. 6C, 6D and 6E schematically illustrate the bias voltages for programming the OTP memory cell of the second embodiment to a second storage state;

FIGS. 6F and 6G schematically illustrate the bias voltages for performing a read action on the OTP memory cell of the second embodiment;

FIG. 7A schematically illustrates a first exemplary structure of a memory cell array composed of a plurality of OTP memory cells in the second embodiment of the present invention;

FIG. 7B schematically illustrates the bias voltages for performing an on-test action on the memory cell array shown in FIG. 7A;

FIG. 7C schematically illustrates the bias voltages for performing an off-test action on the memory cell array shown in FIG. 7A;

FIG. 8 schematically illustrates a second exemplary structure of a memory cell array composed of a plurality of OTP memory cells in the second embodiment of the present invention;

FIG. 9A is a schematic cross-sectional view illustrating the structure of the ROM memory cell in a first storage state;

FIG. 9B is a schematic cross-sectional view illustrating the structure of the ROM memory cell in a second storage state;

FIG. 10A schematically illustrates the bias voltages for performing a read action on the ROM memory cell c11 of the present invention; and

FIG. 10B schematically illustrates the bias voltages for performing a read action on the ROM memory cell c12 of the present invention.

### DETAILED DESCRIPTION OF PREFERRED EMBODIMENTS

The present invention provides a memory cell and a memory cell array of a non-volatile memory. For example, the memory cell is a memory cell of an antifuse-type OTP memory or a memory cell of a Mask ROM.

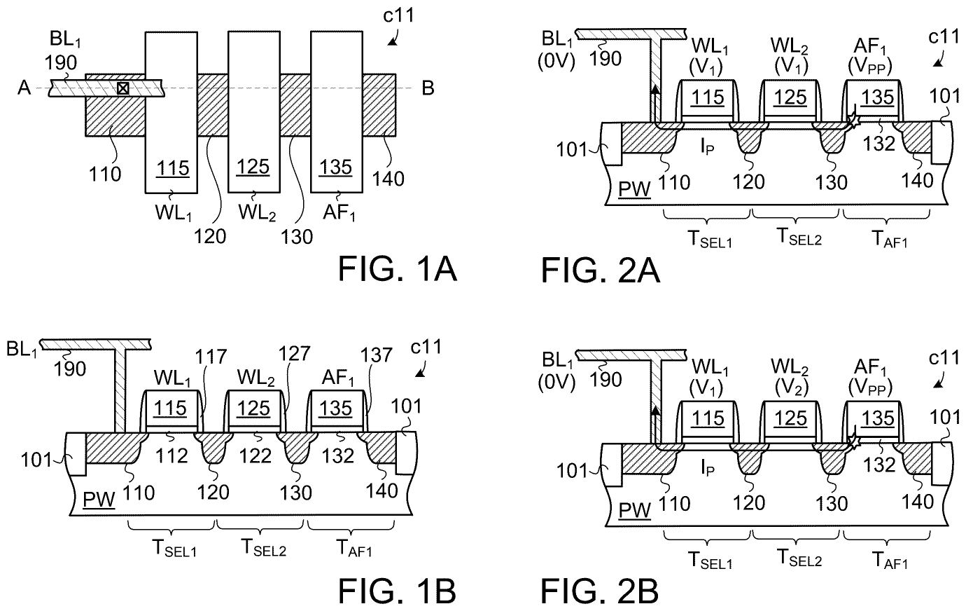

FIG. 1A is a schematic top view illustrating an antifuse-type OTP memory cell according to a first embodiment of the present invention. FIG. 1B is a schematic cross-sectional view illustrating the antifuse-type OTP memory cell according to the first embodiment of the present invention and taken along the direction AB. For brevity, the antifuse-type OTP memory cell will be referred to as an OTP memory cell.

In FIGS. 1A and 1B, the structure of an OTP memory cell c11 is shown. Firstly, a surface of a P-well region PW is exposed through an isolation structure 101. Then, three gate structures are formed over the P-well region PW. The first gate structure includes a gate dielectric layer 112, a gate layer 115 and a spacer 117. The second gate structure includes a gate dielectric layer 122, a gate layer 125 and a spacer 127. The third gate structure includes a gate dielectric layer 132, a gate layer 135 and a spacer 137. Then, a first doped region 110, a second doped region 120, a third doped region 130 and a fourth doped region 140 are formed under the surface of the P-well region PW. The first doped region 110 is located bedside a first side of the first gate structure. The second doped region 120 is arranged between the second side of the first gate structure and the first side of the second gate structure. The third doped region 130 is arranged between the second side of the second gate structure and the first side of the third gate structure. The fourth doped region 140 is located beside the second side of the third gate structure. For example, the four doped regions 110, 120, 130 and 140 are N-type doped regions.

In the OTP memory cell c11, the first doped region 110, the second doped region 120 and the first gate structure are collaboratively formed as a first select transistor T_{SEL1}, the second doped region 120, the third doped region 130 and the second gate structure are collaboratively formed as a second select transistor T_{SEL2}, and the third doped region 130, the fourth doped region 140 and the third gate structure are collaboratively formed as an antifuse transistor T_{AF1}. In other words, the OTP memory cell c11 of this embodiment may be referred as a 3T memory cell, and the three transistors are N-type transistors.

It is noted that numerous modifications may be made while retaining the teachings of the present invention. For example, in some other embodiments, the P-well region PW is replaced by an N-well region, and the N-type doped regions are replaced by P-type regions. In other words, the three transistors in the OTP memory cell c11 are P-type transistors.

The first doped region 110 is electrically connected with a metal line 190 through a contact hole. The metal line 190 is formed in a metal layer above the OTP memory cell c11. In addition, the metal line 190 is served as a first bit line BL₁. The gate layer 115 is served as a first word line WL₁. The gate layer 125 is served as a second word line WL₂. The gate layer 135 is served as a first antifuse line AF₁.

In the OTP memory cell c11, the first terminal of the first select transistor T_{SEL1} is connected with the first bit line BL₁, the gate terminal of the first select transistor T_{SEL1} is connected with the first word line WL₁, the first terminal of the second select transistor T_{SEL2} is connected with the second terminal of the first select transistor T_{SEL1}, the gate terminal of the second select transistor T_{SEL2} is connected with the second word line WL₂, the first terminal of the first antifuse transistor T_{AF1} is connected with the second terminal of the second select transistor T_{SEL2}, and the gate terminal of the first antifuse transistor T_{AF1} is connected with the first antifuse line AF₁.

In the OTP memory cell c11, the first select transistor T_{SEL1} is selectively turned on or turned off according to the voltage provided to the first word line WL₁, and the second select transistor T_{SEL2} is selectively turned on or turned off according to the voltage provided to the second word line WL₂. In this embodiment, the two word lines WL₁ and the WL₂ are activated or inactivated simultaneously. For example, when both of the two word lines WL₁ and the WL₂ are activated, both of the two select transistors T_{SEL1} and T_{SEL2} are turned on. Under this circumstance, the OTP memory cell c11 is the selected memory cell, and a program action or a read action can be selectively performed on the selected memory cell. When both of the two word lines WL₁ and the WL₂ are inactivated, both of the two select transistors T_{SEL1} and T_{SEL2} are turned off. Under this circumstance, the OTP memory cell c11 is the unselected memory cell.

Please refer to FIGS. 1A and 1B again. In the OTP memory cell c11, the two select transistors T_{SEL1} and T_{SEL2} are connected with each other in series and connected with the first antifuse line AF¹. Consequently, even if one of the two select transistors T_{SEL1} and T_{SEL2} is unable to be normally turned on, the OTP memory cell c11 can still be operated normally. Due to the structural design of the OTP memory cell c11, the production yield of the memory cell is enhanced. The operating principles of the OTP memory cell c11 will be described in more details as follows.

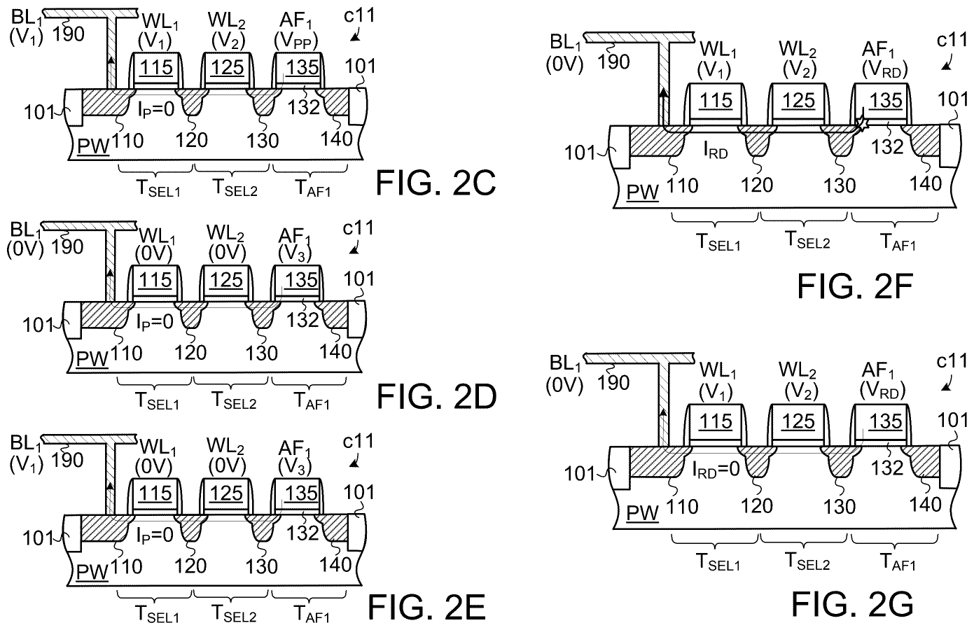

FIGS. 2A and 2B schematically illustrate the bias voltages for programming the OTP memory cell of the first embodiment to a first storage state. FIGS. 2C, 2D and 2E schematically illustrate the bias voltages for programming the OTP memory cell of the first embodiment to a second storage state.

Please refer to FIG. 2A. For programming the OTP memory cell c11 to a first storage state, a ground voltage (0V) is provided to the first bit line BL₁, a first voltage V₁ is provided to the first word line WL₁ and the second word line WL₂, and a program voltage V_{PP} is provided to the first antifuse line AF₁. For example, the first storage state is a ruptured state, the program voltage V_{PP} is in the range between 3V and 6V, and the first voltage V₁ is in the range between 0.4V and 1.7V. The first voltage V₁ may be regarded as the on voltage for turning on the select transistors T_{SEL1} and T_{SEL2}.

When the select transistors T_{SEL1} and T_{SEL2} receive the first voltage V₁ through the word lines WL₁ and the WL₂, the select transistors T_{SEL1} and T_{SEL2} are turned on. Meanwhile, the ground voltage (0V) from the first bit line BL₁ is transmitted to the first antifuse transistor T_{AF1} through the select transistors T_{SEL1} and T_{SEL2}. Consequently, voltage stress withstood by the gate dielectric layer 132 of the first antifuse transistor T_{AF1} is equal to V_{PP}. Since the program voltage V_{PP} exceeds a withstanding threshold voltage, the gate dielectric layer 132 of the first antifuse transistor T_{AF1} is ruptured. Under this circumstance, the OTP memory cell c11 is in a ruptured state. The ruptured gate dielectric layer 132 may be regarded as a low-resistance element having a resistance value of approximately several hundred kOhms or less. Furthermore, since the gate dielectric layer 132 of the first antifuse transistor T_{AF1} is ruptured, the OTP memory cell c11 generates a large programming current I_{P}. The programming current IP flows from the first antifuse line AF₁ to the first bit line BL₁ through the first antifuse transistor T_{AF1}, the second select transistor T_{SEL2} and the first select transistor T_{SEL1}.

Please refer to FIG. 2A again. When the program action is performed, the first voltage V₁ is provided to the first word line WL₁ and the second word line WL₂. Consequently, both of the select transistors T_{SEL1} and T_{SEL2} are turned on. In other words, the first word line WL₁ and the second word line WL₂ of the OTP memory cell c11 can be connected with each other.

Furthermore, the voltages provided to the first word line WL₁ and the second word line WL₂ in the OTP memory cell c11 can also be modified to program the OTP memory cell c11 into the first storage state. Please refer to FIG. 2B. When the program action is performed, the ground voltage (0V) is provided to the first bit line BL₁, the first voltage V₁ is provided to the first word line WL₁, a second voltage V₂ is provided to the second word line WL₂, and the program voltage V_{PP} is provided to the first antifuse line AF₁. Consequently, both of the select transistors T_{SEL1} and T_{SEL2} are turned on, and the OTP memory cell c11 is programmed into the first storage state. For example, the program voltage V_{PP} is higher than the second voltage V₂, and the second voltage V₂ is higher than or equal to the first voltage V₁. The first voltage V₁ is in the range between 0.4V and 1.7V. The second voltage V₂ is in the range between 0.4V and 2.5V.

Please refer to FIG. 2C. When the program action is performed, the first voltage V₁ is provided to the first bit line BL₁ and the first word line WL₁, the second voltage V₂ is provided to the second word line WL₂, and the program voltage V_{PP} is provided to the first antifuse line AF₁. Since both of the first bit line BL₁ and the first word line WL₁ receive first voltage V₁, the first select transistor T_{SEL1} is turned off. Since the voltage stress of the program voltage V_{PP} is not applied to the gate dielectric layer 132 of the first antifuse transistor T_{AF1}, the gate dielectric layer 132 of the first antifuse transistor T_{AF1} is not ruptured. Under this circumstance, the OTP memory cell c11 is maintained in the first storage state, and the programming current IP in the OTP memory cell c11 is very low (or nearly zero). That is, the second storage state is an unruptured state.

Please refer to FIG. 2D. When the program action is performed, the ground voltage (0V) is provided to the first word line WL₁ and the second word line WL₂, and a third voltage V₃ is provided to the first antifuse line AF₁. The third voltage V₃ is lower than the program voltage V_{PP}. The third voltage V₃ is in the range between 0.4V and 4V. The ground voltage (0V) may be regarded as an off voltage to turn off the select transistors T_{SEL1} and T_{SEL2}. In response to the off voltage, the select transistors T_{SEL1} and T_{SEL2} are turned off. Consequently, the gate dielectric layer 132 of the first antifuse transistor T_{AF1} is not ruptured. Under this circumstance, the OTP memory cell c11 is maintained in the unruptured state, and the programming current IP in the OTP memory cell c11 is very low (or nearly zero).

Please refer to FIG. 2E. When the program action is performed, the first voltage V₁ is provided to the first bit line BL₁, the ground voltage (0V) is provided to the first word line WL₁ and the second word line WL₂, and the third voltage V₃ is provided to the first antifuse line AF₁. Consequently, the select transistors T_{SEL1} and T_{SEL2} are turned off, and the gate dielectric layer 132 of the first antifuse transistor T_{AF1} is not ruptured. Under this circumstance, the OTP memory cell c11 is maintained in the unruptured state, and the programming current I_{P} in the OTP memory cell c11 is very low (or nearly zero).

FIGS. 2F and 2G schematically illustrate the bias voltages for performing a read action on the OTP memory cell of the first embodiment. When the read action is performed on the OTP memory cell c11, the ground voltage (0V) is provided to the first bit line BL₁, the first voltage V₁ is provided to the first word line WL₁ and the second word line WL₂, and a read voltage V_{RD} is provided to the first antifuse line AF₁. The read voltage V_{RD} is in the range between 0.4V and 1.6V, and the first voltage V₁ is higher than or equal to the read voltage V_{RD}.

Please refer to FIG. 2F. When the first voltage V₁ from first word line WL₁ and the second word line WL₂ are received by the select transistors T_{SEL1} and T_{SEL2}, the select transistors T_{SEL1} and T_{SEL2} are turned on. Since the OTP memory cell c11 is in the first storage state (i.e., the ruptured state) and the gate dielectric layer 132 is in the low-resistance state, the OTP memory cell c11 generates a larger read current I_{RD}. The read current I_{RD} flows from the first antifuse line AF₁ to the first bit line BL₁ through the first antifuse transistor T_{AF1}, the second select transistor T_{SEL2} and the first select transistor T_{SEL1}.

Please refer to FIG. 2G. When the first voltage V₁ from first word line WL₁ and the second word line WL₂ are received by the select transistors T_{SEL1} and T_{SEL2}, the select transistors T_{SEL1} and T_{SEL2} are turned on. Since the OTP memory cell c11 is in the second storage state (i.e., the unruptured state, a read current I_{RD} generated by the OTP memory cell c11 is very low (or nearly zero).

As shown in FIGS. 2F and 2G, the magnitude of the read current I_{RD} generated by the OTP memory cell c11 is determined according to the storage state of the OTP memory cell c11. In an embodiment, the non-volatile memory is equipped with a comparator (not shown) to determine the storage state of the OTP memory cell c11. The comparator receives a reference current and the read current I_{RD}. If the read current I_{RD} is higher than the reference current, an output signal from the comparator is in a first logic level state, indicating that the OTP memory cell c11 is in the first storage state. Whereas, if the read current I_{RD} is higher than the reference current, the output signal from the comparator is in a low logic level state, indicating that the OTP memory cell c11 is in the second storage state.

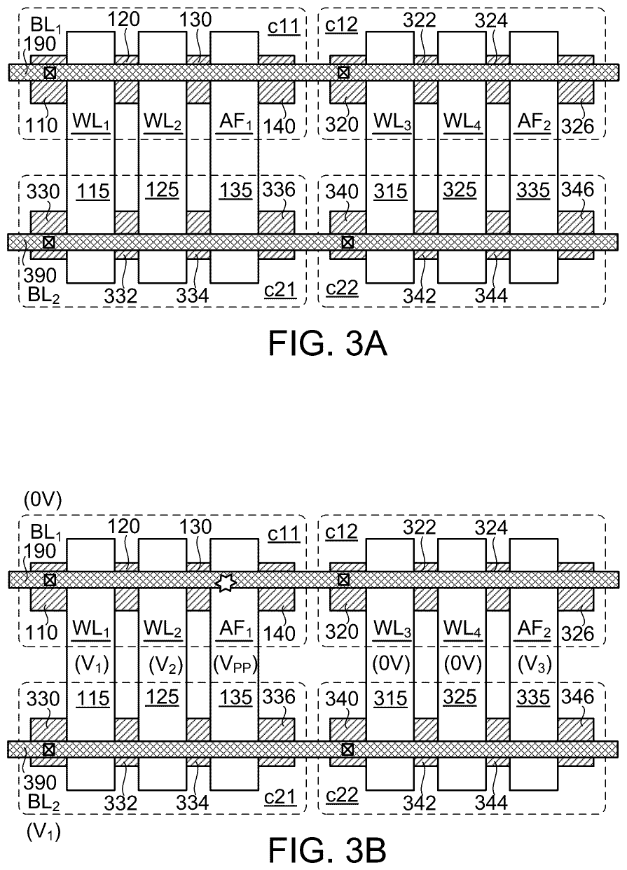

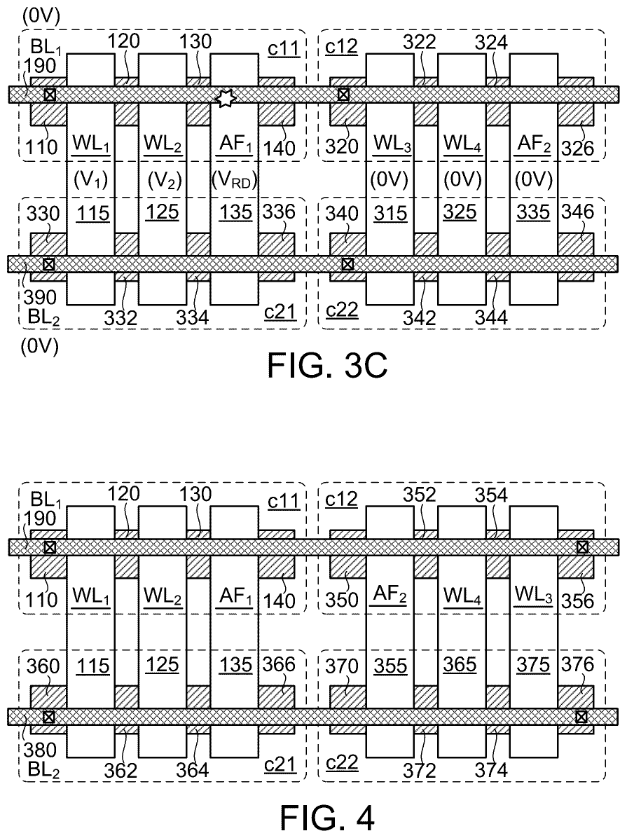

FIG. 3A schematically illustrates a first exemplary structure of a memory cell array composed of a plurality of OTP memory cells in the first embodiment of the present invention. As shown in FIG. 3A, the memory cell array includes a plurality of OTP memory cells which are arranged in an M×N array, wherein M×N is a positive integer greater than 1. For succinctness, only four OTP memory cells c11˜c22 in a 2×2 array arrangement are shown. The structure of each of the memory cells c11˜c22 is similar to the structure of the OTP memory cell c11 shown in FIGS. 1A and 1B, and not redundantly described herein. For brevity, only the structures of the four OTP memory cells c12˜c22 will be described in more details as follows.

In the OTP memory cell c12, the doped region 320, the doped region 322 and a gate structure between the two doped region 320, 322 are collaboratively formed as a first select transistor, the doped region 322, the doped region 324 and a gate structure between the two doped region 322, 324 are collaboratively formed as a second select transistor, and the doped region 324, the doped region 326 and a gate structure between the two doped region 324, 326 are collaboratively formed as an antifuse transistor. The gate layer 315 is served as a third word line WL₃. The gate layer 325 is served as a fourth word line WL₄. The gate layer 335 is served as a second antifuse line AF₂. Furthermore, the doped region 320 is electrically connected with the metal line 190 through a contact hole, and the metal line 190 is served as a first bit line BL₁.

In the OTP memory cell c21, the doped region 330, the doped region 332 and a gate structure between the two doped region 330, 332 are collaboratively formed as a first select transistor, the doped region 332, the doped region 334 and a gate structure between the two doped region 332, 334 are collaboratively formed as a second select transistor, and the doped region 334, the doped region 336 and a gate structure between the two doped region 334, 336 are collaboratively formed as an antifuse transistor. Furthermore, the doped region 330 is electrically connected with a metal line 390 through a contact hole, and the metal line 390 is served as a second bit line BL₂.

In the OTP memory cell c22, the doped region 340, the doped region 342 and a gate structure between the two doped region 340, 342 are collaboratively formed as a first select transistor, the doped region 342, the doped region 344 and a gate structure between the two doped region 342, 344 are collaboratively formed as a second select transistor, and the doped region 344, the doped region 346 and a gate structure between the two doped region 344, 346 are collaboratively formed as an antifuse transistor. Furthermore, the doped region 340 is electrically connected with the metal line 390 through a contact hole.

FIG. 3B schematically illustrates the bias voltages for programming the memory cell array shown in FIG. 3A. For example, the OTP memory cell c11 is programmed into the first storage state, and the other OTP memory cells c12˜c22 are maintained in the second storage state.

When the program action is performed, the ground voltage (0V) is provided to the first bit line BL₁, the first voltage V₁ is provided to the second bit line BL₂, the first voltage V₁ is provided to the first word line WL₁, the second voltage V₂ is provided to the second word line WL₂, the ground voltage (0V) is provided to the third word line WL₃ and the fourth word line WL₄, the program voltage V_{PP} is provided to the first antifuse line AF₁, and the third voltage V₃ is provided to the second antifuse line AF₂. In the OTP memory cell c11, the gate dielectric layer of the antifuse transistor is ruptured. Consequently, the OTP memory cell c11 is in the first storage state (i.e., the ruptured state), and the other OTP memory cells c12˜c22 are maintained in the second storage state. The operations of the OTP memory cells c11˜c22 are similar to those shown in FIGS. 2B, 2C, 2D and 2E, and not redundantly described herein.

FIG. 3C schematically illustrates the bias voltages for performing a read action on the memory cell array shown in FIG. 3A. For example, the read action is performed on the OTP memory cells c11 and c21.

When the read action is performed, the ground voltage (0V) is provided to the first bit line BL₁ and the second bit line BL₂, the first voltage V₁ is provided to the first word line WL₁, the second voltage V₂ is provided to the second word line WL₂, the ground voltage (0V) is provided to the third word line WL₃ and the fourth word line WL₄, the read voltage V_{RD} is provided to the first antifuse line AF₁, and the ground voltage (0V) is provided to the second antifuse line AF₂. In the OTP memory cell c11, the gate dielectric layer of the antifuse transistor is ruptured. Consequently, a larger read current flows through the first bit line BL₁. Under this circumstance, it is determined that the OTP memory cell c11 is in the first storage state. In the OTP memory cell c21, the gate dielectric layer of the antifuse transistor is not ruptured. Consequently, a smaller read current (or nearly zero) flows through the second bit line BL₂. Under this circumstance, it is determined that the OTP memory cell c21 is in the first storage state. The operations of the OTP memory cells c11 and c21 are similar to those shown in FIGS. 2F and 2G, and not redundantly described herein.

In the OTP memory cells c12 and c22, the third word line WL₃ and the fourth word line WL₄ receive the ground voltage (0V). Consequently, the OTP memory cells c12 and c22 do not generate the read current.

Of course, in case that the read action is performed on the OTP memory cell c11 in the memory cell array of FIG. 3B only, the voltage received by the second bit line BL₂ may be replaced by the first voltage V₁. According to the read current on the first bit line BL₁, the storage state of the OTP memory cell c11 can be determined. However, the storage state of the OTP memory cell c21 cannot be determined according to the read current on the second bit line BL₂.

FIG. 4 schematically illustrates a second exemplary structure of a memory cell array composed of a plurality of OTP memory cells in the first embodiment of the present invention. In comparison with the memory cell array of FIG. 3A, the layout arrangement of the memory cell array of FIG. 4 is distinguished. However, the connecting relationship between associated circuit components is similar. The purpose is to prevent competitors from determining the connecting relationship between circuit components when a reverse engineering process is performed.

In the OTP memory cell c12, the doped region 356, the doped region 354 and a gate structure between the two doped region 356, 354 are collaboratively formed as a first select transistor, the doped region 354, the doped region 352 and a gate structure between the two doped region 354, 352 are collaboratively formed as a second select transistor, and the doped region 352, the doped region 350 and a gate structure between the two doped region 352, 350 are collaboratively formed as an antifuse transistor. The gate layer 375 is served as a third word line WL₃. The gate layer 365 is served as a fourth word line WL₄. The gate layer 355 is served as a second antifuse line AF₂. Furthermore, the doped region 356 is electrically connected with the metal line 190 through a contact hole, and the metal line 190 is served as a first bit line BL₁.

In the OTP memory cell c21, the doped region 360, the doped region 362 and a gate structure between the two doped region 360, 362 are collaboratively formed as a first select transistor, the doped region 362, the doped region 364 and a gate structure between the two doped region 362, 364 are collaboratively formed as a second select transistor, and the doped region 364, the doped region 366 and a gate structure between the two doped region 364, 366 are collaboratively formed as an antifuse transistor. Furthermore, the doped region 360 is electrically connected with a metal line 380 through a contact hole, and the metal line 380 is served as a second bit line BL₂.

In the OTP memory cell c22, the doped region 376, the doped region 374 and a gate structure between the two doped region 376, 374 are collaboratively formed as a first select transistor, the doped region 374, the doped region 372 and a gate structure between the two doped region 374, 372 are collaboratively formed as a second select transistor, and the doped region 372, the doped region 370 and a gate structure between the two doped region 372, 370 are collaboratively formed as an antifuse transistor. Furthermore, the doped region 376 is electrically connected with the metal line 380 through a contact hole.

When the program action is performed on the memory cell array of FIG. 4, the bias voltages applied to the memory cell array are similar to those of FIG. 3B. When the read action is performed on the memory cell array of FIG. 4, the bias voltages applied to the memory cell array are similar to those of FIG. 3C.

Generally, after the non-volatile memory is manufactured, many testing processes need to be carried out. After the non-volatile memory passes the testing processes and it is ensured that the non-volatile memory is operated normally, the non-volatile memory can be shipped to customers. However, after the non-volatile memory leaves the factory, all OTP memory cells c11˜c22 in the memory cell array are in the unruptured state. The testing processes are unable to judge whether the select transistors T_{SEL1} and T_{SEL2} in the OTP memory cells c11˜c22 are operated normally or generate subthreshold leakage currents. After the non-volatile memory is delivered to the customer for use and an OTP memory cell in the memory cell array is programmed to the rupture state, if the select transistors T_{SEL1} and T_{SEL2} of the OTP memory cell generate leakage currents and fail to be operated normally, other OTP memory cells connected with the same bit line cannot be operated normally.

Take the memory cell array of FIG. 3A for example. It is assumed that the OTP memory cell c11 is programmed into the ruptured state and the select transistors T_{SEL1} and T_{SEL2} of the OTP memory cell c11 generate leakage currents. When the read action is performed, the OTP memory cell c11 continuously outputs the leakage current to the first bit line BL₁, and another OTP memory cell c12 connected with the first bit line BL₁ is influenced. That is, even if the OTP memory cell c12 is in the unruptured state, the leakage current from the OTP memory cell c12 is influenced by the leakage current when the read action is performed. Consequently, the storage state of the OTP memory cell c12 is misjudged to be in the ruptured state. Similarly, if there are 128 OTP memory cells are connected with the first bit line BL₁, these OTP memory cells are misjudged to be in the ruptured state when the read action is performed.

In order to overcome the above drawbacks, the structure of the OTP memory cell needs to be further improved.

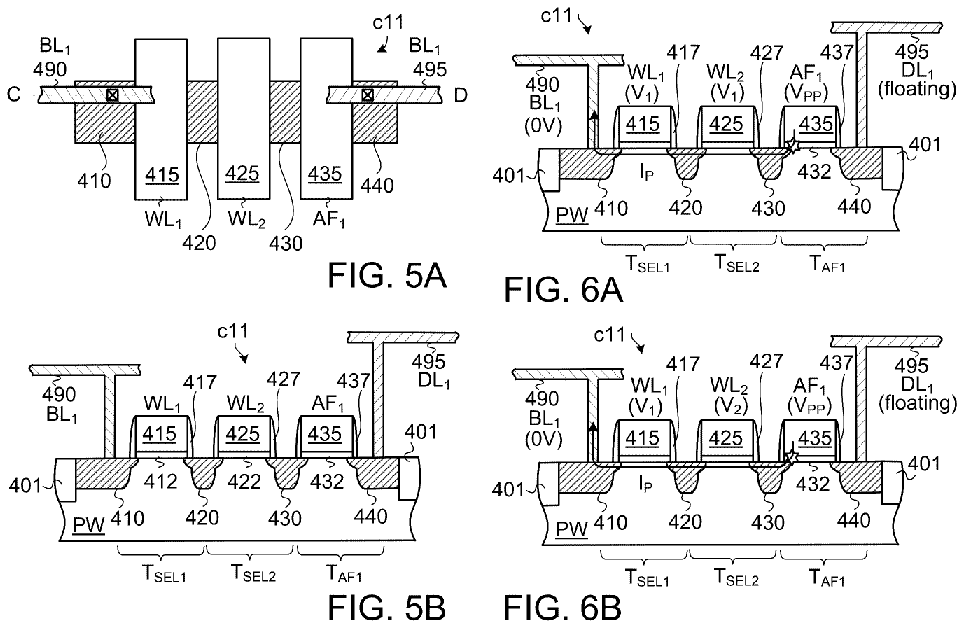

FIG. 5A is a schematic top view illustrating an antifuse-type OTP memory cell according to a second embodiment of the present invention. FIG. 5B is a schematic cross-sectional view illustrating the antifuse-type OTP memory cell according to the second embodiment of the present invention and taken along the direction CD. For brevity, the antifuse-type OTP memory cell will be referred to as an OTP memory cell.

In FIGS. 5A and 5B, the structure of an OTP memory cell c11 is shown. The OTP memory cell c11 is constructed in a P-well region PW. Firstly, a surface of a P-well region PW is exposed through an isolation structure 401. Then, three gate structures are formed over the P-well region PW. The first gate structure includes a gate dielectric layer 412, a gate layer 415 and a spacer 417. The second gate structure includes a gate dielectric layer 422, a gate layer 425 and a spacer 427. The third gate structure includes a gate dielectric layer 432, a gate layer 435 and a spacer 437. Then, a first doped region 410, a second doped region 420, a third doped region 430 and a fourth doped region 440 are formed under the surface of the P-well region PW. For example, the four doped regions 410, 420, 430 and 440 are N-type doped regions.

In the OTP memory cell c11, the first doped region 410, the second doped region 420 and the first gate structure are collaboratively formed as a first select transistor T_{SEL1}, the second doped region 420, the third doped region 430 and the second gate structure are collaboratively formed as a second select transistor T_{SEL2}, and the third doped region 430, the fourth doped region 440 and the third gate structure are collaboratively formed as an antifuse transistor T_{AF1}. In other words, the OTP memory cell c11 of this embodiment may be referred as a 3T memory cell, and the three transistors are N-type transistors.

It is noted that numerous modifications may be made while retaining the teachings of the present invention. For example, in some other embodiments, the P-well region PW is replaced by an N-well region, and the N-type doped regions are replaced by P-type regions. In other words, the three transistors in the OTP memory cell c11 are P-type transistors.

The first doped region 410 is electrically connected with a metal line 490 through a contact hole. The metal line 490 is formed in a metal layer above the OTP memory cell c11. In addition, the metal line 490 is served as a first bit line BL₁. The fourth doped region 440 is electrically connected with another metal line 495 through a contact hole. The metal line 495 is served as a first detecting line DL₁. The two metal lines 490 and 495 are not in contact with each other. Furthermore, the gate layer 415 is served as a first word line WL₁, the gate layer 425 is served as a second word line WL₂, and the gate layer 435 is served as a first antifuse line AF₁.

In the OTP memory cell c11, the first select transistor T_{SEL1} is selectively turned on or turned off according to the voltage provided to the first word line WL₁, and the second select transistor T_{SEL2} is selectively turned on or turned off according to the voltage provided to the second word line WL₂. In this embodiment, the two word lines WL₁ and the WL₂ are activated or inactivated simultaneously. For example, when both of the two word lines WL₁ and the WL₂ are activated, both of the two select transistors T_{SEL1} and T_{SEL2} are turned on. Under this circumstance, the OTP memory cell c11 is the selected memory cell, and a program action or a read action can be selectively performed on the selected memory cell. When both of the two word lines WL₁ and the WL₂ are inactivated, both of the two select transistors T_{SEL1} and T_{SEL2} are turned off. Under this circumstance, the OTP memory cell c11 is the unselected memory cell.

Similarly, due to the structural design of the OTP memory cell c11, the production yield of the memory cell is enhanced. Furthermore, the first detecting line DL₁ in the OTP memory cell c11 is used in the testing process. When other actions are performed, the first detecting line DL₁ is in the floating state.

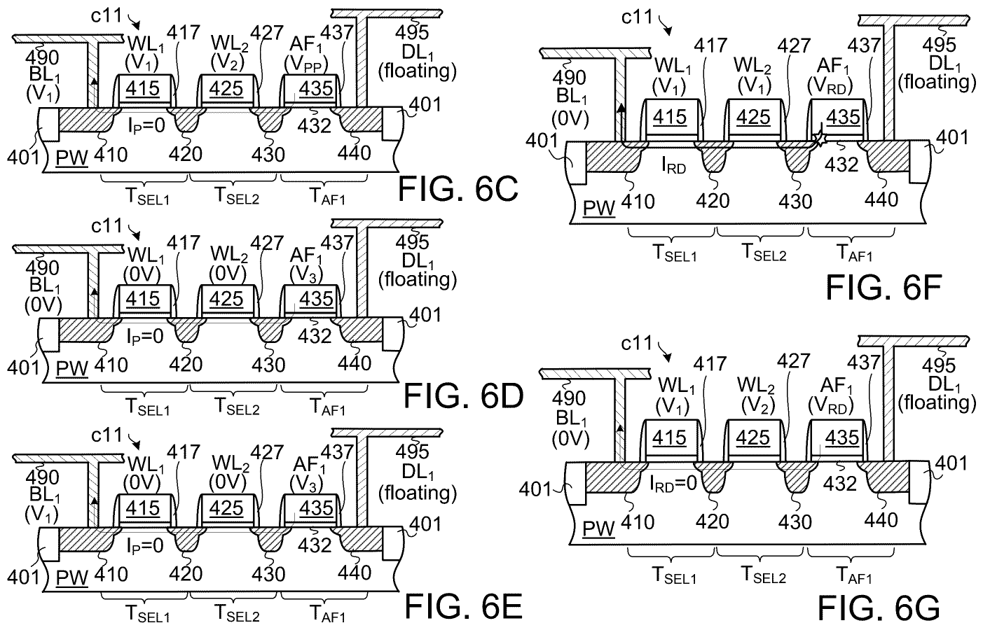

FIGS. 6A and 6B schematically illustrate the bias voltages for programming the OTP memory cell of the second embodiment to a first storage state. FIGS. 6C, 6D and 6E schematically illustrate the bias voltages for programming the OTP memory cell of the second embodiment to a second storage state.

In the program actions of FIGS. 6A to 6E, the first detecting line DL₁ is in the floating state, and the voltages received by other terminals and the operating principles are similar to those shown in FIGS. 2A to 2E.

FIGS. 6F and 6G schematically illustrate the bias voltages for performing a read action on the OTP memory cell of the second embodiment. In the program actions of FIGS. 6F to 6G, the first detecting line DL₁ is in the floating state, and the voltages received by other terminals and the operating principles are similar to those shown in FIGS. 2F and 2G.

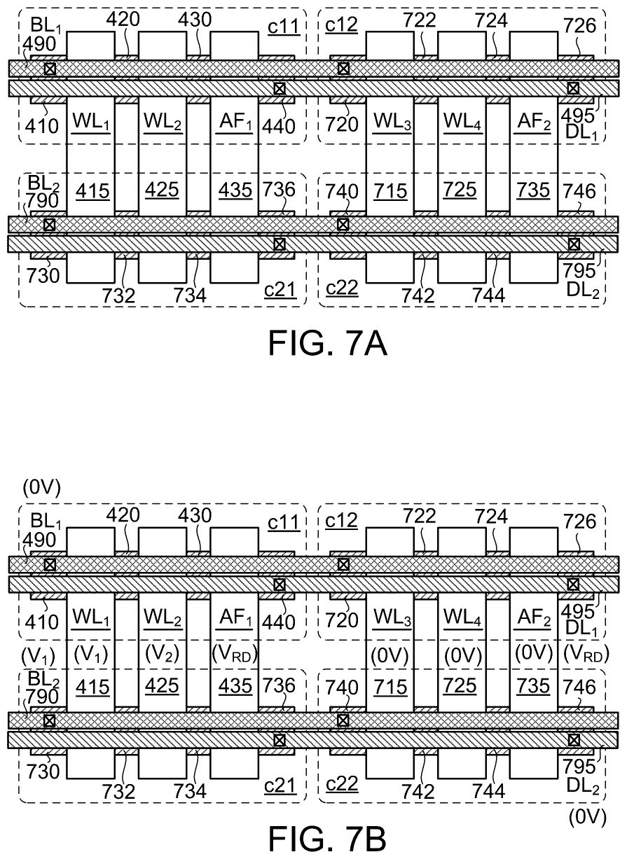

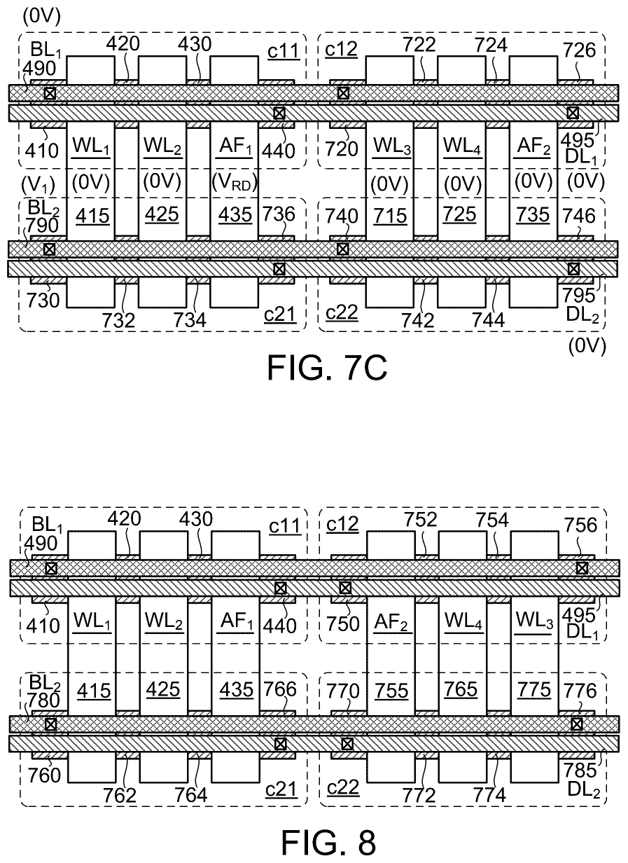

FIG. 7A schematically illustrates a first exemplary structure of a memory cell array composed of a plurality of OTP memory cells in the second embodiment of the present invention. As shown in FIG. 7A, the memory cell array includes a plurality of OTP memory cells which are arranged in an M×N array, wherein M×N is a positive integer greater than 1. For succinctness, only four OTP memory cells c11˜c22 in a 2×2 array arrangement are shown. The structure of each of the memory cells c11˜c22 is similar to the structure of the OTP memory cell c11 shown in FIGS. 5A and 5B, and not redundantly described herein. The structures of the four OTP memory cells c12˜c22 will be described in more details as follows.

In the OTP memory cell c12, the doped region 720, the doped region 722 and a gate structure between the two doped region 720, 722 are collaboratively formed as a first select transistor, the doped region 722, the doped region 724 and a gate structure between the two doped region 722, 724 are collaboratively formed as a second select transistor, and the doped region 724, the doped region 726 and a gate structure between the two doped region 724, 726 are collaboratively formed as an antifuse transistor. The gate layer 715 is served as a third word line WL₃. The gate layer 725 is served as a fourth word line WL₄. The gate layer 735 is served as a second antifuse line AF₂. Furthermore, the doped region 720 is electrically connected with a metal line 790 through a contact hole. In addition, the metal line 790 is served as a first bit line BL₁. The doped region 726 is electrically connected with a metal line 795 through a contact hole. The metal line 795 is served as a second detecting line DL₂. The two metal lines 790 and 795 are not in contact with each other.

In the OTP memory cell c21, the doped region 730, the doped region 732 and a gate structure between the two doped region 730, 732 are collaboratively formed as a first select transistor, the doped region 732, the doped region 734 and a gate structure between the two doped region 732, 734 are collaboratively formed as a second select transistor, and the doped region 734, the doped region 736 and a gate structure between the two doped region 734, 736 are collaboratively formed as an antifuse transistor. Furthermore, the doped region 730 is electrically connected with the metal line 790 through a contact hole, and the metal line 790 is served as a second bit line BL₂. The doped region 736 is electrically connected with a metal line 795 through a contact hole. The metal line 795 is served as the second detecting line DL₂. The two metal lines 790 and 795 are not in contact with each other.

In the OTP memory cell c22, the doped region 740, the doped region 742 and a gate structure between the two doped region 740, 742 are collaboratively formed as a first select transistor, the doped region 742, the doped region 744 and a gate structure between the two doped region 742, 744 are collaboratively formed as a second select transistor, and the doped region 744, the doped region 746 and a gate structure between the two doped region 744, 746 are collaboratively formed as an antifuse transistor. Furthermore, the doped region 740 is electrically connected with the metal line 790 through a contact hole, and the doped region 746 is electrically connected with the metal line 795 through a contact hole.

When the program action is performed on the memory cell array of FIG. 7A, the first detecting line DL₁ and the second detecting line DL₂ are in the floating state, and the voltages received by other terminals and the operating principles are similar to those shown in FIG. 3B. Similarly, when the read action is performed on the memory cell array of FIG. 7A, the first detecting line DL₁ and the second detecting line DL₂ are in the floating state, and the voltages received by other terminals and the operating principles are similar to those shown in FIG. 3C.

FIG. 7B schematically illustrates the bias voltages for performing an on-test action on the memory cell array shown in FIG. 7A. FIG. 7C schematically illustrates the bias voltages for performing an off-test action on the memory cell array shown in FIG. 7A. For brevity, only the on-test action and the off-test action performed on the OTP memory cell c11 will be described. The on-test action and the off-test action are used to judge whether the two switch transistors in the OTP memory cell c11 are operated normally. Similarly, the on-test action and the off-test action can be used to test the other OTP memory cells c12˜c22 of the memory cell array.

For example, when the test process is performed on the OTP memory cell c11, the antifuse transistor may be referred as a third select transistor. In response to the voltage received by the first antifuse line AF₁, the antifuse transistor is selectively turned on or turned off.

Please refer to FIG. 7B. When the on-test action is performed, the ground voltage (0V) is provided to the first bit line BL₁, the first voltage V₁ is provided to the second bit line BL₂, the first voltage V₁ is provided to the first word line WL₁, the second voltage V₂ is provided to the second word line WL₂, the ground voltage (0V) is provided to the third word line WL₃ and the fourth word line WL₄, the read voltage V_{RD} is provided to the first antifuse line AF₁, the ground voltage (0V) is provided to the second antifuse line AF₂, the read voltage V_{RD} is provided to the first detecting line DL₁, and the ground voltage (0V) is provided to the second detecting line DL₂.

In the OTP memory cell c11, all of the first select transistor, the second select transistor and the antifuse transistor are turned on. Consequently, a larger test current is generated in the OTP memory cell c11. The test current flows from the first detecting line DL₁ to the first bit line BL₁ through the antifuse transistor, the second select transistor and the first select transistor. That is, if a test current exceeding a specified current value flows through the first bit line BL₁ when the on-test action is performed on the OTP memory cell c11, it means that the first select transistor and the second select transistor are operated normally. In other words, the OTP memory cell c11 passes the on-test action.

Please refer to FIG. 7C. When the off-test action is performed, the ground voltage (0V) is provided to the first bit line BL₁, the first voltage V₁ is provided to the second bit line BL₂, the ground voltage (0V) is provided to the first word line WL₁, the second word line WL₂, the ground voltage (0V) is provided to the third word line WL₃ and the fourth word line WL₄, the read voltage V_{RD} is provided to the first antifuse line AF₁, the ground voltage (0V) is provided to the second antifuse line AF₂, and the ground voltage (0V) is provided to the first detecting line DL₁ and the second detecting line DL₂.

In the OTP memory cell c11, the first select transistor and the second select transistor are turned off. The test current generated in the OTP memory cell c11 is very low (nearly zero). That is, the test current flowing through the first bit line BL₁ is very low (nearly zero) when the off-test action is performed on the OTP memory cell c11, it means that the first select transistor and the second select transistor are turned off normally. In other words, the OTP memory cell c11 passes the off-test action. Whereas, if the test current flowing through the first bit line BL₁ is very large, it means that the first select transistor and the second select transistor generate leakage currents. Since the test current is too large, the OTP memory cell c11 is unable to pass the off-test action.

For example, in case that the OTP memory cell c11 passes the on-test action and the off-test action, the OTP memory cell c11 is a normal memory cell. Consequently, the OTP memory cell c11 can be programmed into the first storage state by the user. Whereas, in case that the OTP memory cell c11 is unable to pass the on-test action or the off-test action, the OTP memory cell c11 is marked as a failed memory cell. Under this circumstance, the OTP memory cell c11 cannot be programmed into the first storage state by the user.

On the other hand, when the on-test action or the off-test action is performed, the transistors in the other OTP memory cells c12˜c22 of the memory cell array are not all turned on. Consequently, the test current is not generated.

FIG. 8 schematically illustrates a second exemplary structure of a memory cell array composed of a plurality of OTP memory cells in the second embodiment of the present invention. In comparison with the memory cell array of FIG. 7A, the layout arrangement of the memory cell array of FIG. 8 is distinguished. However, the connecting relationship between associated circuit components is similar. The purpose is to prevent competitors from determining the connecting relationship between circuit components when a reverse engineering process is performed.

In the OTP memory cell c12, the doped region 756, the doped region 754 and a gate structure between the two doped region 756, 754 are collaboratively formed as a first select transistor, the doped region 754, the doped region 752 and a gate structure between the two doped region 754, 752 are collaboratively formed as a second select transistor, and the doped region 752, the doped region 750 and a gate structure between the two doped region 752, 750 are collaboratively formed as an antifuse transistor. The gate layer 775 is served as a third word line WL₃. The gate layer 765 is served as a fourth word line WL₄. The gate layer 755 is served as a second antifuse line AF₂. Furthermore, the doped region 756 is electrically connected with the metal line 490 through a contact hole, and the metal line 490 is served as a first bit line BL₁. The doped region 750 is electrically connected with a metal line 495 through a contact hole. The metal line 495 is served as a first detecting line DL₁.

In the OTP memory cell c21, the doped region 760, the doped region 762 and a gate structure between the two doped region 760, 762 are collaboratively formed as a first select transistor, the doped region 762, the doped region 764 and a gate structure between the two doped region 762, 764 are collaboratively formed as a second select transistor, and the doped region 764, the doped region 766 and a gate structure between the two doped region 764, 766 are collaboratively formed as an antifuse transistor. Furthermore, the doped region 760 is electrically connected with a metal line 780 through a contact hole, and the metal line 780 is served as a second bit line BL₂. The doped region 766 is electrically connected with a metal line 785 through a contact hole. The metal line 785 is served as the second detecting line DL₂.

In the OTP memory cell c22, the doped region 776, the doped region 774 and a gate structure between the two doped region 776, 774 are collaboratively formed as a first select transistor, the doped region 774, the doped region 772 and a gate structure between the two doped region 774, 773 are collaboratively formed as a second select transistor, and the doped region 772, the doped region 770 and a gate structure between the two doped region 772, 770 are collaboratively formed as an antifuse transistor. Furthermore, the doped region 776 is electrically connected with the metal line 780 through a contact hole, and the doped region 770 is electrically connected with the metal line 785 through a contact hole.

When the program action, the read action and the test process is performed on the memory cell array of FIG. 8, the bias voltages applied to the memory cell array are similar to bias voltages applied to memory cell array of FIG. 7A, and not redundantly described herein.

Since the gate dielectric layer of the antifuse transistor is not ruptured, the antifuse transistor may be referred as a third select transistor. Consequently, the structure of the OTP memory c11 in the second embodiment may be modified as a mask read only memory cell, which is referred as a ROM memory cell. After the non-volatile memory leaves the factory, all stored data in the ROM memory cell have been recorded therein. The user is only able to read the stored data from the ROM memory cell, but the user is unable to program the ROM memory cell.

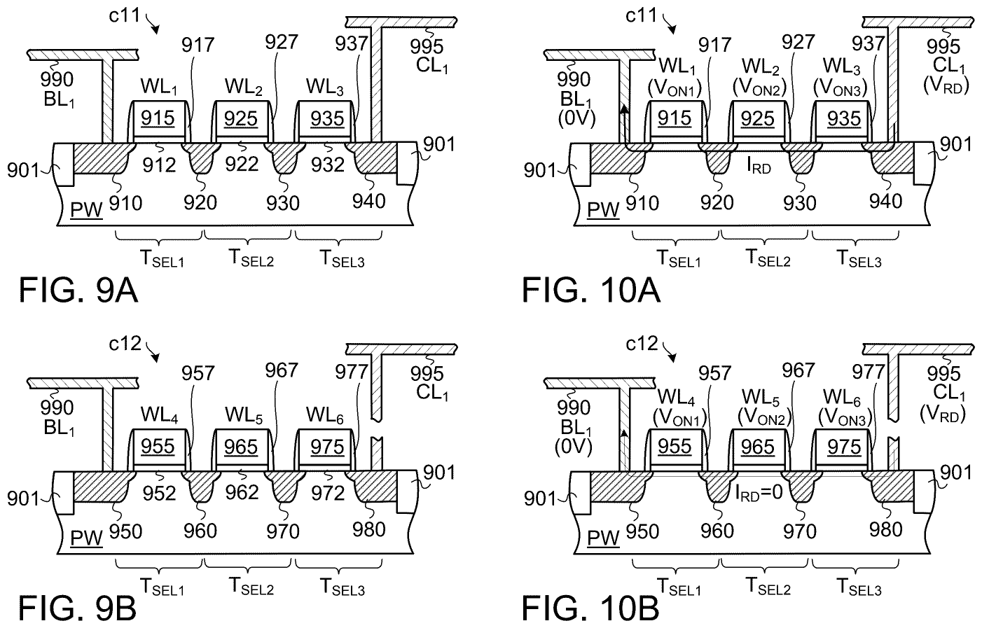

FIG. 9A is a schematic cross-sectional view illustrating the structure of the ROM memory cell in a first storage state. The ROM memory cell c11 is constructed in a P-well region PW. Firstly, a surface of a P-well region PW is exposed through an isolation structure 901. Then, three gate structures are formed over the P-well region PW. The first gate structure includes a gate dielectric layer 912, a gate layer 915 and a spacer 917. The second gate structure includes a gate dielectric layer 922, a gate layer 925 and a spacer 927. The third gate structure includes a gate dielectric layer 932, a gate layer 935 and a spacer 937. Then, a first doped region 910, a second doped region 920, a third doped region 930 and a fourth doped region 940 are formed under the surface of the P-well region PW. For example, the four doped regions 910, 920, 930 and 940 are N-type doped regions.

In the ROM memory cell c11, the first doped region 910, the second doped region 920 and the first gate structure are collaboratively formed as a first select transistor T_{SEL1}, the second doped region 920, the third doped region 930 and the second gate structure are collaboratively formed as a second select transistor T_{SEL2}, and the third doped region 930, the fourth doped region 940 and the third gate structure are collaboratively formed as a third transistor T_{SEL3}. In other words, the ROM memory cell c11 of this embodiment may be referred as a 3T memory cell, and the three transistors are N-type transistors.

It is noted that numerous modifications may be made while retaining the teachings of the present invention. For example, in some other embodiments, the P-well region PW is replaced by an N-well region, and the N-type doped regions are replaced by P-type regions. In other words, the three transistors in the ROM memory cell c11 are P-type transistors.

The first doped region 910 is electrically connected with a metal line 990 through a contact hole. The metal line 990 is formed in a metal layer above the ROM memory cell c11. In addition, the metal line 990 is served as a first bit line BL₁. The fourth doped region 940 is electrically connected with another metal line 995 through a contact hole. The metal line 995 is formed in a metal layer above the ROM memory cell c11. The metal line 995 is served as a first control line CL₁. Furthermore, the gate layer 915 is served as a first word line WL₁, the gate layer 925 is served as a second word line WL₂, and the gate layer 935 is served as a third word line WL₃.

FIG. 9B is a schematic cross-sectional view illustrating the structure of the ROM memory cell in a second storage state. The ROM memory cells c11 and c12 can be collaboratively formed as a 1×2 memory cell array.

The ROM memory cell c12 is constructed in the P-well region PW. Firstly, the surface of the P-well region PW is exposed through the isolation structure 901. Then, three gate structures are formed over the P-well region PW. The first gate structure includes a gate dielectric layer 952, a gate layer 955 and a spacer 957. The second gate structure includes a gate dielectric layer 962, a gate layer 965 and a spacer 967. The third gate structure includes a gate dielectric layer 972, a gate layer 975 and a spacer 977. Then, a first doped region 950, a second doped region 960, a third doped region 970 and a fourth doped region 980 are formed under the surface of the P-well region PW. For example, the four doped regions 950, 960, 970 and 980 are N-type doped regions.

In the ROM memory cell c12, the first doped region 950, the second doped region 960 and a gate structure between the two doped region 950, 960 are collaboratively formed as a first select transistor T_{SEL1}, the second doped region 960, the third doped region 970 and a gate structure between the two doped region 960, 970 are collaboratively formed as a second select transistor T_{SEL2}, and the third doped region 970, the fourth doped region 980 and a gate structure between the two doped region 970, 980 are collaboratively formed as a third transistor T_{SEL3}. In other words, the ROM memory cell c12 of this embodiment may be referred as a 3T memory cell, and the three transistors are N-type transistors.

It is noted that numerous modifications may be made while retaining the teachings of the present invention. For example, in some other embodiments, the P-well region PW is replaced by an N-well region, and the N-type doped regions are replaced by P-type regions. In other words, the three transistors in the ROM memory cell c12 are P-type transistors.

The first doped region 950 is electrically connected with the metal line 990 through a contact hole. In addition, the metal line 990 is served as the first bit line BL₁. The fourth doped region 980 is not electrically connected with the metal line 995. Furthermore, the gate layer 955 is served as a fourth word line WL₄, the gate layer 965 is served as a fifth word line WL₅, and the gate layer 975 is served as a sixth word line WL₆.

FIG. 10A schematically illustrates the bias voltages for performing a read action on the ROM memory cell c11 of the present invention. When the read action is performed on the ROM memory cell c11, the ground voltage (0V) is provided to the first bit line BL₁, a first on voltage V_{ON1} is provided to the first word line WL₁, a second on voltage V_{ON2} is provided to the second word line WL₂, a third on voltage V_{ON3} is provided to the third word line WL₃, and a read voltage V_{RD} is provided to the first control line CL₁. In addition, the ground voltage (0V) is provided to the fourth word line WL₄, the fifth word line WL₅ and the sixth word line WL₆ of the ROM memory cell c12 (not shown).

The third on voltage V_{ON3} is greater than or equal to the second on voltage V_{ON2}. The second on voltage V_{ON2} is greater than or equal to the first on voltage V_{ON1}. The first on voltage V_{ON1} is greater than or equal to the read voltage V_{RD}. For example, the first on voltage V_{ON1} is in the range between 0.4V and 1.7V, the second on voltage V_{ON2} is in the range between 0.4V and 2.5V, the third on voltage V_{ON3} is in the range between 0.4V and 2.8V, and the read voltage V_{RD} is in the range between 0.4V and 1.6V.

Please refer to FIG. 10A again. When the select transistors T_{SEL1}, T_{SEL2} and T_{SEL3} respectively receive the on voltages V_{ON1}, V_{ON2} and V_{ON3} from the word lines WL₁, WL₂ and WL₃, the ROM memory cell c11 generates a larger read current I_{RD}. The read current I_{RD} flows to the first bit line BL₁ through the third transistor T_{SEL3}, the second select transistor T_{SEL2} and first select transistor T_{SEL1}.

FIG. 10B schematically illustrates the bias voltages for performing a read action on the ROM memory cell c12 of the present invention. When the read action is performed on the ROM memory cell c12, the ground voltage (0V) is provided to the first bit line BL₁, the first on voltage V_{ON1} is provided to the fourth word line WL₄, the second on voltage V_{ON2} is provided to the fifth word line WL₅, the third on voltage V_{ON3} is provided to the sixth word line WL₆, and the read voltage V_{RD} is provided to the first control line CL₁. In addition, the ground voltage (0V) is provided to the first word line WL₁, the second word line WL₂ and the third word line WL₃ of the ROM memory cell c11 (not shown).

Please refer to FIG. 10B again. Since the first control line CL₁ is not electrically connected with the third transistor T_{SEL3}, the read current I_{RD} generated by the ROM memory cell c12 is very low (nearly zero).

As shown in FIGS. 10A and 10B, the magnitude of the read current I_{RD} generated by the ROM memory cell c11 or c12 is determined according to the storage state. According to the magnitude of the read current I_{RD}, it is determined that the ROM memory cell c11 is in the first storage state and the ROM memory cell c12 is in the second storage state.

From the above descriptions, the present invention provides a memory cell and a memory cell array of a non-volatile memory. The memory cell is an OTP memory cell. After the structure of the memory cell is simply modified, the memory cell of the non-volatile memory cell may be used the ROM memory cell. In the above embodiments, the transistors in the memory cell are planar transistors. It is noted that the examples of the transistors are not restricted. For example, in some other embodiments, each planar transistor in the OTP memory cell or the ROM memory cell may be replaced by a FinFET transistor or a GAA transistor. It should be noted that the position of the first bit line BL₁, the second bit line BL₂, the first detecting line DL₁, the second detecting line DL₂ and the first control line CL₁ and the spacing between the two metal lines in FIG. 1A to FIG. 10B are merely illustrative examples and are not drawn to real size.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A memory cell array of a non-volatile memory comprising a first antifuse-type one time programmable memory cell, wherein the first antifuse-type one time programmable memory cell comprises:
a first select transistor, wherein a first terminal of the first select transistor is connected with a first bit line, and a gate terminal of the first select transistor is connected with a first word line;
a second select transistor, wherein a first terminal of the second select transistor is connected with a second terminal of the first select transistor, and a gate terminal of the second select transistor is connected with a second word line; and
a first antifuse transistor, wherein a first terminal of the first antifuse transistor is connected with a second terminal of the second select transistor, and a gate terminal of the first antifuse transistor is connected with a first antifuse line,
wherein when a program action is performed on the first antifuse-type one time programmable memory cell, a ground voltage is provided to the first bit line, a program voltage is provided to the first antifuse line, and both of the first select transistor and the second select transistor are turned on simultaneously, so that a gate dielectric layer of the first antifuse transistor is ruptured and the first antifuse-type one time programmable memory cell is programmed into a ruptured state.

2. The memory cell array as claimed in claim 1, wherein when the program action is performed, a first voltage is provided to the first word line and the second word line, so that the first select transistor and the second select transistor are turned on, wherein the program voltage is greater than the first voltage.

3. The memory cell array as claimed in claim 2, wherein the first word line and the second word line are connected with each other.

4. The memory cell array as claimed in claim 1, wherein when the program action is performed, a first voltage is provided to the first word line, and a second voltage is provided to the second word line, so that both of the first select transistor and the second select transistor are turned on, wherein the program voltage is greater than the second voltage, and the second voltage is greater than or equal to the first voltage.

5. The memory cell array as claimed in claim 1, wherein when a read action is performed on the first antifuse-type one time programmable memory cell, a ground voltage is provided to the first bit line, a read voltage is provided to the first antifuse line, and both of the first select transistor and the second select transistor are turned on, so that the first antifuse-type one time programmable memory cell generates a read current, wherein a storage state of the first antifuse-type one time programmable memory cell is determined according to the read current.

6. The memory cell array as claimed in claim 1, wherein the first antifuse-type one time programmable memory cell comprises:
a first gate structure, a second gate structure and a third gate structure formed over a surface of a well region;
a first doped region, a second doped region, a third doped region and a fourth doped region formed under the surface of the well region, wherein the first doped region is located bedside a first side of the first gate structure, the second doped region is arranged between a second side of the first gate structure and a first side of the second gate structure, a third doped region is arranged between a second side of the second gate structure and a first side of the third gate structure, and the fourth doped region is located beside a second side of the third gate structure; and
a first metal line electrically connected with the first doped region, wherein the first metal line is the first bit line,
wherein the first doped region, the second doped region and the first gate structure are collaboratively formed as the first select transistor, the second doped region, the third doped region and the second gate structure are collaboratively formed as the second select transistor, and the third doped region, the fourth doped region and the third gate structure are collaboratively formed as the antifuse transistor,
wherein a gate layer of the first gate structure is the first word line, a gate layer of the second gate structure is the second word line, and a gate layer of the third gate structure is the first antifuse line.

7. The memory cell array as claimed in claim 1, wherein a second terminal of the first antifuse transistor is connected with a first detecting line, wherein when the program action is performed, the first detecting line is in a floating state.

8. The memory cell array as claimed in claim 7, wherein when a read action is performed, a ground voltage is provided to the first bit line, a read voltage is provided to the first antifuse line, the first detecting line is in a floating state, and the first select transistor and the second select transistor are turned on, so that the first antifuse-type one time programmable memory cell generates a read current, wherein a storage state of the first antifuse-type one time programmable memory cell is determined according to the read current.

9. The memory cell array as claimed in claim 7, wherein when an on-test action is performed on the first antifuse-type one time programmable memory cell in a test process, the ground voltage is provided to the first bit line, the first voltage is provided to the first word line, a second voltage is provided to the second word line, and a read voltage is provided to the first antifuse line and the first detecting line, so that the first antifuse-type one time programmable memory cell generates a test current, wherein the first select transistor and the second select transistor are determined to be normally turned on or not according to a magnitude of the test current, wherein the second voltage is greater than or equal to the first voltage, and the first voltage is greater than or equal to the read voltage.

10. The memory cell array as claimed in claim 9, wherein when an off-test action is performed on the first antifuse-type one time programmable memory cell in a test process, the ground voltage is provided to the first bit line, the first word line, the second word line and the first detecting line, and a read voltage is provided to the first antifuse line, so that the first antifuse-type one time programmable memory cell generates a test current, wherein the first select transistor and the second select transistor are determined to be normally turned off or not according to a magnitude of the test current.

11. The memory cell array as claimed in claim 10, wherein the program action is performed on the first antifuse-type one time programmable memory cell when the first select transistor and the second select transistor are determined to be normally turned on and normally turned off, and the program action is not performed on the first antifuse-type one time programmable memory cell when the first select transistor and the second select transistor are determined not to be normally turned on or normally turned off.

12. The memory cell array as claimed in claim 7, wherein the first antifuse-type one time programmable memory cell comprises:
a first gate structure, a second gate structure and a third gate structure formed over a surface of a well region;
a first doped region, a second doped region, a third doped region and a fourth doped region formed under the surface of the well region, wherein the first doped region is located bedside a first side of the first gate structure, the second doped region is arranged between a second side of the first gate structure and a first side of the second gate structure, a third doped region is arranged between a second side of the second gate structure and a first side of the third gate structure, and the fourth doped region is located beside a second side of the third gate structure;
a first metal line electrically connected with the first doped region, wherein the first metal line is the first bit line; and
a second metal line electrically connected with the fourth doped region, wherein the second metal line is the first detecting line,
wherein the first doped region, the second doped region and the first gate structure are collaboratively formed as the first select transistor, the second doped region, the third doped region and the second gate structure are collaboratively formed as the second select transistor, and the third doped region, the fourth doped region and the third gate structure are collaboratively formed as the antifuse transistor,
wherein a gate layer of the first gate structure is the first word line, a gate layer of the second gate structure is the second word line, and a gate layer of the third gate structure is the first antifuse line.

13. The memory cell array as claimed in claim 7, wherein the memory cell array further comprises a second antifuse-type one time programmable memory cell, and the second antifuse-type one time programmable memory cell comprises:
a third select transistor, wherein a first terminal of the third select transistor is connected with the first bit line, and a gate terminal of the third select transistor is connected with a third word line;
a fourth select transistor, wherein a first terminal of the fourth select transistor is connected with a second terminal of the third select transistor, and a gate terminal of the fourth select transistor is connected with a fourth word line; and
a second antifuse transistor, wherein a first terminal of the second antifuse transistor is connected with a second terminal of the fourth select transistor, a second terminal of the second antifuse transistor is connected with the first detecting line, and a gate terminal of the second antifuse transistor is connected with a second antifuse line.

14. The memory cell array as claimed in claim 13, wherein the memory cell array further comprises a third antifuse-type one time programmable memory cell, and the third antifuse-type one time programmable memory cell comprises:
a fifth select transistor, wherein a first terminal of the fifth select transistor is connected with a second bit line, and a gate terminal of the fifth select transistor is connected with the first word line;
a sixth select transistor, wherein a first terminal of the sixth select transistor is connected with a second terminal of the fifth select transistor, and a gate terminal of the sixth select transistor is connected with the second word line; and
a third antifuse transistor, wherein a first terminal of the third antifuse transistor is connected with a second terminal of the sixth select transistor, a second terminal of the third antifuse transistor is connected with a second detecting line, and a gate terminal of the third antifuse transistor is connected with the first antifuse line.

15. The memory cell array as claimed in claim 14, wherein the memory cell array further comprises a fourth antifuse-type one time programmable memory cell, and the fourth antifuse-type one time programmable memory cell comprises:
a seventh select transistor, wherein a first terminal of the seventh select transistor is connected with the second bit line, and a gate terminal of the seventh select transistor is connected with the third word line;
an eighth select transistor, wherein a first terminal of the eighth select transistor is connected with a second terminal of the seventh select transistor, and a gate terminal of the eighth select transistor is connected with the fourth word line; and
a fourth antifuse transistor, wherein a first terminal of the fourth antifuse transistor is connected with a second terminal of the eighth select transistor, a second terminal of the fourth antifuse transistor is connected with the second detecting line, and a gate terminal of the fourth antifuse transistor is connected with the second antifuse line.
